(19) United States
(12) Patent Application Publication
(10) Pub. No.: US 2026/0061507 A1
(43) Pub. Date: Mar. 5, 2026

(54) Method and System for Soldering Flexible Printed Circuit

(71) Applicant: Guangdong Mingji Hi-Tech Electronics Co., Ltd., Dongguan (CN)

(72) Inventors: Hongzhuo ZHANG, Dongguan (CN); Yajun YANG, Dongguan (CN); Chengfu WANG, Dongguan (CN)

(21) Appl. No.: 18/960,585

(22) Filed: Nov. 26, 2024

(30) Foreign Application Priority Data
Aug. 27, 2024 (CN) 2024111853798

(51) Int. Cl. B23K 1/00; B23K 1/005; B23K 3/047; B23K 3/08; B23K 101/42; H05K 3/34

(52) U.S. Cl. CPC B23K 1/0016; B23K 1/0056; B23K 3/0478; B23K 3/08; H05K 3/341; B23K 2101/42; H05K 2203/107

(57) ABSTRACT

Method and System for Soldering Flexible Printed Circuit, wherein the soldering method comprises: S100: creating windows in flexible flat cable; S200: applying solder paste at window positions; S300: performing solder paste inspection; S400: attaching double-sided tape near the solder paste; S500: adhering and assembling branch circuit boards at double-sided tape positions; S600: soldering branch circuit boards to flexible flat cable at window positions. This method involves no pollution during production, achieves high processing precision, and maintains low production costs.

### CROSS-REFERENCE TO RELATED APPLICATIONS

The present application claims priority to Chinese Patent Application No. 2024111853798, filed on Aug. 27, 2024, the entire disclosure of which is incorporated herein by reference.

### TECHNICAL FIELD

This application relates to the field of wastewater treatment technology, specifically to the method and system for soldering flexible printed circuit.

### BACKGROUND TECHNOLOGY

Flexible Printed Circuit (FPC). In the manufacturing field of Cells Contact System (CCS) for new energy battery packs, the industry typically uses traditional FPC for electrical signal collection. While FPC can meet product functional requirements, it has relatively high manufacturing costs. Moreover, traditional FPC manufacturing uses etching processes which are not environmentally friendly-creating a contradiction with the environmental protection goals of new energy adoption.

Therefore, the industry is researching and developing a flexible flat cable connect flexible die-cut circuit to replace traditional designs. Currently, some have proposed using Flexible Flat Cable (FFC) connected to Flexible Die-cutting Circuit (FDC) to create a flexible flat cable connect flexible die-cut circuit (abbreviated as FCC). The current production process for this new product uses reflow soldering and high-current pulse soldering methods.

However, the applicant has identified the following deficiencies in current processes: reflow soldering may have cold solder joint quality issues, and due to process specifics, requires the entire product to pass through the furnace for whole-board soldering, leading to increased product protection costs and fixture costs, making it unsuitable for FCC-type product soldering manufacturing; high-current pulse soldering is a single-point local soldering method which, while suitable for FCC-type product soldering manufacturing, results in longer soldering times and may burn FFC insulation, posing certain quality risks. Additionally, local single-point soldering leads to increased labor costs, indirectly causing higher processing costs.

Therefore, there is an urgent need to develop a method and system for soldering flexible printed circuit with good soldering quality and low cost.

### SUMMARY OF INVENTION

This application aims to solve at least one of the aforementioned technical problems to some extent.

The first objective of this application is to propose a provide for soldering flexible printed circuit with good soldering quality and low cost.

The second objective of this application is to propose a system for soldering flexible printed circuit.

To achieve these objectives, the first aspect of this application discloses a method for soldering flexible printed circuit, comprising the following steps: S100: Creating windows in flexible flat cable or flexible flat cable film to expose conductors of the flexible flat cable at window positions; S200: Applying solder paste at window positions of the flexible flat cable; S300: Performing solder paste inspection; inspecting solder paste height, volume, area, short circuits and offset, and compensating relevant data information to downstream equipment to ensure precision; S400: Attaching double-sided tape near the solder paste; S500: Adhering and assembling branch circuit boards at double-sided tape positions; S600: Soldering the branch circuit boards to the flexible flat cable at window positions to produce flexible printed circuits.

Additionally, the method for soldering flexible printed circuit according to the above technical solution of this application may have the following additional technical features:

Optionally, during the applying process of step S200, visual positioning is adopted, with three-axis platform performing solder paste application operations; during step S500 of adhering and assembling branch circuit boards, visual positioning is adopted to automatically recognize soldering positions through target capture for precise assembly positioning; prior to soldering in step S600, visual positioning is first adopted to guide precise positioning of soldering head at soldering area.

Optionally, solder paste applied in step S200 is laser-specific solder paste; soldering in step S600 is laser soldering.

Optionally, prior to soldering in step S600, range finder is also used for distance measurement to monitor product height position information and adjust soldering head height and laser soldering focal length.

Optionally, during soldering in step S600, temperature at soldering position is monitored; when detected soldering temperature deviates from set temperature, laser driver is driven to automatically compensate power to adjust laser soldering temperature, making actual soldering temperature match set temperature.

To achieve the above objectives, the second aspect of this application proposes a system for soldering flexible printed circuit, comprising: Window creation module for creating windows in flexible flat cable or flexible flat cable film to expose conductors of flexible flat cable at window positions; Solder application module for applying solder paste at window positions of the flexible flat cable; Solder paste inspection module for inspecting solder paste height, volume, area, short circuits and offset, and compensating relevant data information to downstream equipment to ensure precision; Tape application module for attaching double-sided tape near the solder paste; Component placement module for adhering and assembling branch circuit boards at double-sided tape positions; Soldering module for soldering the branch circuit boards to the flexible flat cable at window positions to produce flexible printed circuits.

Optionally, further comprising: First visual positioning module installed in the solder application module's three-axis platform, adopting visual positioning during three-axis platform solder paste application operations; Second visual positioning module installed in the component placement module, adopting visual positioning during branch circuit board adhesion and assembly to automatically recognize soldering positions through target capture for precise assembly positioning; Third visual positioning module installed in the soldering module for adopting visual positioning prior to soldering to guide precise positioning of soldering head at soldering area.

Optionally, further comprising: Laser-specific solder paste storage compartment installed in the solder application module for providing laser-specific solder paste during solder paste application; Laser generator and laser soldering head installed in the soldering module for performing laser soldering.

Optionally, further comprising: Range finder installed in the soldering module for distance measurement prior to soldering to monitor product height position information and adjust soldering head height and laser soldering focal length.

Optionally, further comprising: Temperature monitoring module installed in the soldering module for monitoring temperature at soldering position during soldering; when detected soldering temperature deviates from set temperature, driving laser driver to automatically compensate power to adjust laser soldering temperature, making actual soldering temperature match set temperature.

Beneficial effects of this application include: 1. No pollution during production process; 2. High processing precision and guaranteed product soldering quality and reliability; 3. High production efficiency and low production costs.

### BRIEF DESCRIPTION OF DRAWINGS

FIG. 1 is a flow chart of a method for soldering flexible printed circuit provided by an embodiment of this application;

FIG. 2 is a structural block diagram of a system for soldering flexible printed circuit provided by an embodiment of this application;

FIG. 3 is an equipment diagram of a system for soldering flexible printed circuit provided by an embodiment of this application.

### DETAILED DESCRIPTION OF EMBODIMENTS

The embodiments of this application are described in detail below, with examples of the embodiments shown in the accompanying drawings, wherein the same or similar reference numerals throughout indicate the same or similar elements or components/elements having the same or similar functions. The embodiments described below with reference to the drawings are exemplary and explanatory only, and should not be construed as limiting the scope of this invention.

The following describes the method and system for soldering flexible printed circuit of this application's embodiments in conjunction with the drawings.

FIG. 1 is a flow chart of a method for soldering flexible printed circuit provided by an embodiment of this application. As shown in FIG. 1, the method for soldering flexible printed circuit comprises the following steps: S100: Creating windows in flexible flat cable or flexible flat cable film to expose conductors of the flexible flat cable at window positions; S200: Applying solder paste at window positions of the flexible flat cable; S300: Performing solder paste inspection; inspecting solder paste height, volume, area, short circuits and offset, and compensating relevant data information to downstream equipment to ensure precision; S400: Attaching double-sided tape near the solder paste; S500: Adhering and assembling branch circuit boards at double-sided tape positions; S600: Soldering the branch circuit boards to the flexible flat cable at window positions to produce flexible printed circuits.

Specifically, the mentioned branch circuit board is generally a Flexible Die-cutting Circuit (FDC), though in special cases it can also be a small flexible printed circuit. The method of this application is: Using Flexible Flat Cable (FFC) as the base material, punching windows in the insulation film of the FFC to expose portions of conductors, forming window sections (i.e., window positions); then soldering a branch circuit board, specifically a Flexible Die-cutting Circuit (FDC), at the window sections to produce the flexible printed circuit of this embodiment. The applicant refers to this as FCC, which stands for Flexible flat cable connect flexible die-cut circuit, meaning FFC connected to FDC. The flexible printed circuit FCC does not use traditional flexible printed circuit (FPC) materials that require etching processes in manufacturing, nor does the production process involve steps that cause chemical pollution, thereby ensuring both the new process flow and manufactured products are environmentally friendly.

It should be noted that in this application's embodiments, the flexible flat cable used can be either finished products or semi-finished products. Specifically, windows can be created on finished flexible flat cables using machine tools to remove the surface film and expose internal conductors; alternatively, semi-finished products can be used, where holes are stamped in the flexible flat cable film using a punch press, followed by a film covering process to produce the finished flexible flat cable. This application seeks to protect the window creation process step as one of the key steps in FCC production, rather than the production process of flexible flat cable itself.

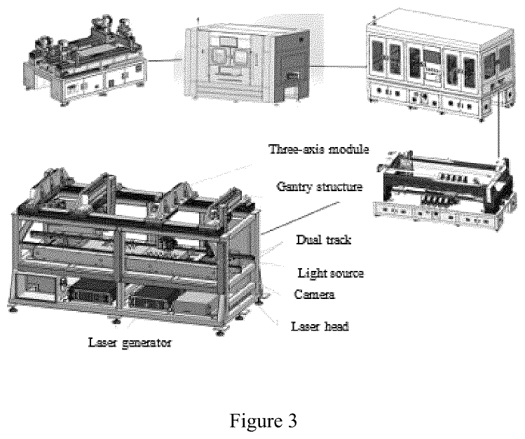

After completing the window creation process, the production enters a continuous production line for steps S200-S600. The specific equipment is shown in FIG. 3: For some key process equipment in FIG. 3, the outer covers have been removed to show the internal production line and processing components, with connection lines illustrating the process flow. First is the solder paste printer in the upper left, performing step S200, applying solder paste at window positions; then entering the next equipment—Solder Paste Inspection (SPI) equipment, performing step S300, inspecting solder paste height, volume, area, short circuits and offset after printing to enhance the processing precision of downstream operations; next the production line moves workpieces to the next equipment—double-sided tape application equipment, performing step S400, attaching double-sided tape near solder paste positions, with this tape serving to secure branches (i.e., FDC or small-sized FPC) for convenient assembly in subsequent processes and stable operation; next the production line moves workpieces to the next equipment—pick-and-place machine, performing step S500, adhering and assembling branch circuit boards at double-sided tape positions, with these branch circuit boards precisely secured in correct positions by the double-sided tape from the previous process, ensuring no displacement occurs during product movement or soldering process; finally the production line moves fixture to the next equipment—soldering machine, using soldering head to melt solder paste at window positions, reliably soldering branch circuit boards to FFC to produce flexible printed circuit FCC.

According to the method of the present invention for soldering flexible printed circuit, there is no pollution during production; SPI equipment ensures processing precision, and combined with double-sided tape application and component placement processes, guarantees product soldering quality and reliability; production efficiency is high and production costs are low.

According to the embodiment of the present invention, during the applying process of step S200, visual positioning is adopted, with three-axis platform performing solder paste application operations; during step S500 of adhering and assembling branch circuit boards, visual positioning is adopted to automatically recognize soldering positions through target capture for precise assembly positioning; prior to soldering in step S600, visual positioning is first adopted to guide precise positioning of soldering head at soldering area.

Specifically, visual positioning devices can be configured on solder paste printer, pick-and-place machine and soldering machine to improve processing precision. In step S500, the pick-and-place machine assembles branches with visual positioning system for automatic target capture to recognize soldering positions and achieve precise assembly positioning.

According to an embodiment of this application, solder paste applied in step S200 is laser-specific solder paste; soldering in step S600 is laser soldering.

Specifically, since laser soldering is contactless, no customized soldering heads are required, reducing fixture costs and consumable usage, offering advantages of high soldering efficiency with guaranteed quality and efficiency, and lower manufacturing costs compared to reflow soldering and high-current pulse soldering, making it suitable for mass production.

When using laser soldering, laser generator can be configured in laser soldering machine to drive laser soldering head. Semiconductor laser with 915 nm wavelength, 200 W˜300 W power can be used.

According to an embodiment of this application, prior to soldering in step S600, range finder is also used for distance measurement to monitor product height position information and adjust soldering head height and laser soldering focal length.

Specifically, laser soldering machine uses three-axis module to control soldering head movement along three coordinate axes, with range finder automatically monitoring product height position and adjusting z-axis height to adapt to laser soldering focal length, ensuring precise soldering and preventing incorrect laser heating positions that could damage equipment or circuit boards.

According to an embodiment of this application, during soldering in step S600, temperature at soldering position is monitored; when detected soldering temperature deviates from set temperature, laser driver is driven to automatically compensate power to adjust laser soldering temperature, making actual soldering temperature match set temperature.

Specifically, infrared temperature monitoring device can be used to monitor temperature, with this device driving laser power to achieve closed-loop temperature control, ensuring stable soldering process, guaranteed soldering quality, and improved product quality.

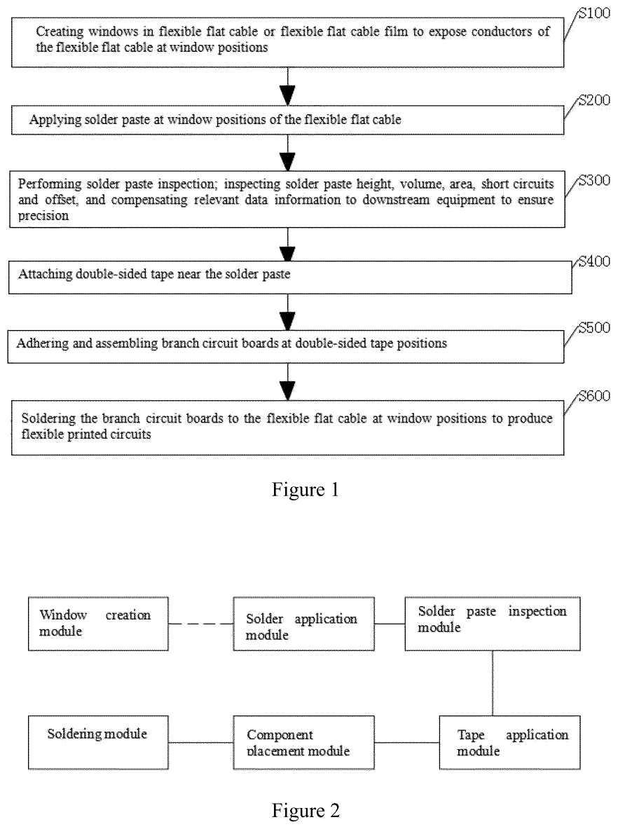

Based on above embodiments, this invention embodiment also proposes a system for soldering flexible printed circuit; FIG. 2 is a structural block diagram of a system for soldering flexible printed circuit provided by an embodiment of this application, FIG. 3 is an equipment diagram of a system for soldering flexible printed circuit provided by an embodiment of this application; as shown in FIGS. 2-3: this system for soldering flexible printed circuit includes: Window creation module for creating windows in flexible flat cable or flexible flat cable film to expose conductors of flexible flat cable at window positions; Solder application module for applying solder paste at window positions of the flexible flat cable; Solder paste inspection module for inspecting solder paste height, volume, area, short circuits and offset, and compensating relevant data information to downstream equipment to ensure precision; Tape application module for attaching double-sided tape near the solder paste; Component placement module for adhering and assembling branch circuit boards at double-sided tape positions; Soldering module for soldering the branch circuit boards to the flexible flat cable at window positions to produce flexible printed circuits.

According to an embodiment of this application, further comprising: First visual positioning module installed in the solder application module's three-axis platform, adopting visual positioning during three-axis platform solder paste application operations; Second visual positioning module installed in the component placement module, adopting visual positioning during branch circuit board adhesion and assembly to automatically recognize soldering positions through target capture for precise assembly positioning; Third visual positioning module installed in the soldering module for adopting visual positioning prior to soldering to guide precise positioning of soldering head at soldering area.

According to an embodiment of this application, further comprising: Laser-specific solder paste storage compartment installed in the solder application module for providing laser-specific solder paste during solder paste application; Laser generator and laser soldering head installed in the soldering module for performing laser soldering.

According to an embodiment of this application, further comprising: Range finder installed in the soldering module for distance measurement prior to soldering to monitor product height position information and adjust soldering head height and laser soldering focal length.

According to an embodiment of this application, further comprising: Temperature monitoring module installed in the soldering module for monitoring temperature at soldering position during soldering; when detected soldering temperature deviates from set temperature, driving laser driver to automatically compensate power to adjust laser soldering temperature, making actual soldering temperature match set temperature.

According to the system of the present invention for soldering flexible printed circuit, there is no pollution during production; SPI equipment ensures processing precision, and combined with double-sided tape application and component placement processes, guarantees product soldering quality and reliability; production efficiency is high and production costs are low.

The above embodiments are preferred implementation schemes of this application. In addition to the described embodiments, alternative implementations of this invention are possible. Any obvious substitutions within the concept of this application are within the protection scope of this application.

1. Method for Soldering Flexible Printed Circuit, characterized in comprising the following steps:
S100: Creating windows in flexible flat cable or flexible flat cable film to expose conductors of the flexible flat cable at window positions;
S200: Applying solder paste at window positions of the flexible flat cable;
S300: Performing solder paste inspection; inspecting solder paste height, volume, area, short circuits and offset, and compensating relevant data information to downstream equipment to ensure precision;
S400: Attaching double-sided tape near the solder paste;
S500: Adhering and assembling branch circuit boards at double-sided tape positions;
S600: Soldering the branch circuit boards to the flexible flat cable at window positions to produce flexible printed circuits.

2. The Method for Soldering Flexible Printed Circuit according to claim 1, characterized in that: during the applying process of step S200, visual positioning is adopted, with three-axis platform performing solder paste application operations;
During the step S500 of adhering and assembling branch circuit boards, visual positioning is adopted to automatically recognize soldering positions through target capture for precise assembly positioning;
Prior to soldering in the step S600, visual positioning is first adopted to guide precise positioning of soldering head at soldering area.

3. The Method for Soldering Flexible Printed Circuit according to claim 1, characterized in that: solder paste applied in the step S200 is laser-specific solder paste; soldering in the step S600 is laser soldering.

4. The Method for Soldering Flexible Printed Circuit according to claim 3, characterized in that: prior to soldering in the step S600, range finder is also used for distance measurement to monitor product height position information and adjust soldering head height and laser soldering focal length.

5. The Method for Soldering Flexible Printed Circuit according to claim 3, characterized in that: during soldering in the step S600, temperature at soldering position is monitored; when detected soldering temperature deviates from set temperature, laser driver is driven to automatically compensate power to adjust laser soldering temperature, making actual soldering temperature match set temperature.

6. The System for Soldering Flexible Printed Circuit, characterized in comprising:
Window creation module for creating windows in flexible flat cable or flexible flat cable film to expose conductors of flexible flat cable at window positions;
Solder application module for applying solder paste at window positions of the flexible flat cable;
Solder paste inspection module for inspecting solder paste height, volume, area, short circuits and offset, and compensating relevant data information to downstream equipment to ensure precision;
Tape application module for attaching double-sided tape near the solder paste;
Component placement module for adhering and assembling branch circuit boards at double-sided tape positions;
Soldering module for soldering the branch circuit boards to the flexible flat cable at window positions to produce flexible printed circuits.

7. The System for Soldering Flexible Printed Circuit according to claim 6, characterized in further comprising:
First visual positioning module installed in the solder application module's three-axis platform, adopting visual positioning during three-axis platform solder paste application operations;
Second visual positioning module installed in the component placement module, adopting visual positioning during branch circuit board adhesion and assembly to automatically recognize soldering positions through target capture for precise assembly positioning;
Third visual positioning module installed in the soldering module for adopting visual positioning prior to soldering to guide precise positioning of soldering head at soldering area.

8. The System for Soldering Flexible Printed Circuit according to claim 6, characterized in further comprising:
Laser-specific solder paste storage compartment installed in the solder application module for providing laser-specific solder paste during solder paste application;
Laser generator and laser soldering head installed in the soldering module for performing laser soldering.

9. The System for Soldering Flexible Printed Circuit according to claim 8, characterized in further comprising: Range finder installed in the soldering module for distance measurement prior to soldering to monitor product height position information and adjust soldering head height and laser soldering focal length.

10. The System for Soldering Flexible Printed Circuit according to claim 8, characterized in further comprising: Temperature monitoring module installed in the soldering module for monitoring temperature at soldering position during soldering; when detected soldering temperature deviates from set temperature, driving laser driver to automatically compensate power to adjust laser soldering temperature, making actual soldering temperature match set temperature.
